(19) United States
(12) Patent Application Publication
(10) Pub. No.: US 2014/0354262 A1
(43) Pub. Date: Dec. 4, 2014

(54) LOCK DETECTOR FOR DIGITAL PHASE-LOCKED LOOP

(71) Applicant: QUALCOMM Incorporated, San Diego, CA (US)

(72) Inventors: Jia-Yi Chen, Sunnyvale, CA (US); Michael Peter Mack, Sunnyvale, CA (US)

(21) Appl. No.: 13/908,804

(22) Filed: Jun. 3, 2013

(51) Int. Cl. G01R 25/00

(52) U.S. Cl. CPC G01R 25/005
USPC 324/76.82

(57) ABSTRACT

A phase locked loop (PLL) lock detector may be configured to observe the phase error signal from a phase comparator of a PLL circuit. The PLL lock detector may accumulate a sum of phase errors and compare the sum of phase errors to determine whether the PLL circuit is locked in phase with the reference signal. Various modifications to the phase error signal and sum of phase errors may be used to improve the efficiency of the PLL lock detector. Configurable settings for the accumulator and a comparator may be used to adjust the operation of the PLL lock detector.

### BACKGROUND

Embodiments of the inventive subject matter generally relate to the field of communications, and, more particularly, to digital phase-locked loop communications.

A phase-locked loop or phase lock loop (PLL) is a common component in communication systems. A PLL is often used to maintain synchronization of transmitted signals. A PLL typically includes a control system that generates an output signal whose phase is related to the phase of an input “reference” signal. Some PLLs include an electronic circuit consisting of a variable frequency oscillator and a phase detector. The circuit compares the phase of the input signal with the phase of the signal derived from its output oscillator and adjusts the frequency of its oscillator to keep the phases matched. The signal from the phase detector is used to control the oscillator in a feedback loop.

Phase-locked loops are widely employed in radio, telecommunications, computers and other electronic applications. They can be used to recover a signal from a noisy communication channel, generate stable frequencies at a multiple of an input frequency (frequency synthesis), or distribute clock timing pulses in digital logic designs such as microprocessors. Since a single integrated circuit can provide a complete phase-locked-loop building block, the technique is widely used in modern electronic devices, with output frequencies from a fraction of a hertz up to many gigahertz.

There are several variations of PLLs. Some terms that are used are analog phase-locked loop (APLL) also referred to as a linear phase-locked loop (LPLL), digital phase-locked loop (DPLL), all digital phase-locked loop (ADPLL). An analog or linear PLL (LPLL) typically includes an analog phase detector and a voltage-controlled oscillator (VCO). A digital PLL (DPLL) is similar to an analog PLL except that a DPLL utilizes a digital phase detector. All digital PLL (ADPLL) is a design in which the phase detector, filter and oscillator are all digital components. A conventional ADPLL utilizes a numerically controlled oscillator (NCO) (sometimes also referred to as a digital controlled oscillator, DCO). Conventional PLL lock detectors determine a lock condition by comparing an output clock signal with an input reference signal.

### SUMMARY

Various embodiments for are described for determining whether a digital phase-locked loop (PLL) circuit is locked in phase with a reference signal. A PLL lock detector provides a lock status based, at least in part, on an accumulation of phase errors from the phase comparator of the PLL circuit.

In one embodiment, a PLL circuit includes a phase comparator configured to periodically determine phase errors based, at least in part, on a comparison of a reference signal and a feedback signal of the PLL circuit. A PLL lock detector is configured to accumulate a sum of the phase errors and to determine whether the PLL circuit is locked in phase with the reference signal based, at least in part, on whether the sum of the phase errors is below a threshold value.

### BRIEF DESCRIPTION OF THE DRAWINGS

The present embodiments may be better understood, and numerous objects, features, and advantages made apparent to those skilled in the art by referencing the accompanying drawings.

FIG. 1 is an example block diagram of a digital phase locked loop (PLL) circuit and PLL lock detector in accordance with various embodiments of the present disclosure.

FIG. 2 is an example block diagram of a basic PLL lock detector in accordance with various embodiments of the present disclosure.

FIG. 3 is an example block diagram of an enhanced PLL lock detector in accordance with various embodiments of the present disclosure.

FIG. 4 is an example block diagram of a particular implementation of a PLL lock detector in accordance with an embodiment of the present disclosure.

FIG. 5 is an example block diagram of a PLL lock detector having overflow condition logic in accordance with various embodiments of the present disclosure.

FIG. 6 is a flow diagram showing example operations for use with a PLL lock detector in accordance with an embodiment of the present disclosure.

FIG. 7 is a flow diagram showing example operations for use with a PLL lock detector in accordance with an embodiment of the present disclosure.

FIG. 8 is another example block diagram of one embodiment of an electronic device including an all-digital PLL circuit and PLL lock detector in accordance with various embodiments of the present disclosure.

### DESCRIPTION OF EMBODIMENT(S)

The description that follows includes exemplary systems, methods, techniques, instruction sequences and computer program products that embody techniques of the present inventive subject matter. However, it is understood that the described embodiments may be practiced without these specific details. For instance, although examples refer to an all-digital phase locked loop circuit, embodiments of the present disclosure may be relevant to other types of digital phase locked loop circuits. In other instances, well-known instruction instances, protocols, structures and techniques have not been shown in detail in order not to obfuscate the description.

A PLL lock detector is a diagnostic circuitry that monitors the PLL control loop to tell if the loop is locked (sometimes also referred to as “settled”). In traditional analog PLLs, the voltage of the control line is monitored to determine if the PLL circuit is locked. In a traditional all-digital PLL, a similar approach may be implemented to monitor the digital control word of the digital-controlled oscillator (DCO). For example, a traditional lock detector for an all-digital PLL may observe a control signal of the oscillator (e.g. “control word”) to determine a lock status.

When the PLL is locked, the control word will be “settled” so the locked detection can be achieved by measuring the fluctuation of the control word. If the fluctuation is small, it represents a stable loop and the lock detector should signify “locked.” However, the digital control word may be a lengthy value (e.g. wide bit-width) to cover a large range of the control frequency. Monitoring fluctuations in the digital control words may be impractical or inefficient. To monitor the fluctuations in the digital control words, multiple adders with wide bit-width are needed to measure the average and delta calculations. Power consumption and space on the integrated circuit are considerations that motivate the use of fewer adders.

In accordance with some embodiments of the present disclosure, a PLL lock detector may be configured to observe the phase error signal from a phase comparator of the PLL circuit. In a locked state, the phase error is expected to be close to zero. Only small amounts of fluctuation may be present in the phase error when the PLL is nearly locked. Since the phase error is small when locked, a smaller bit width value may be used to determine whether the PLL is locked. Using the smaller bit width value may result in smaller adders or less complex circuitry. Therefore, in one embodiment, the lock detector may utilize a much smaller physical area in the circuit board and/or utilize less power than the traditional approach.

In another embodiment, the phase error signal may be modified to further reduce the bit width of the phase error signal while still providing sufficient data to determine whether the PLL circuit is locked in phase with a reference signal. For example, a clipping or truncating operation may reduce the bit width of the phase error signal. The abridged phase error signal may be used with an accumulator to maintain a sum of the phase errors. In one embodiment, the accumulator may be configured to act as a low-pass filter in conjunction with limiting the maximum value of the phase error sum. The phase error sum may be compared with a threshold value to determine whether the PLL is locked. For example, in one embodiment, if a magnitude of the phase error sum is not greater than a threshold value, the lock detector indicates that the PLL circuit is phase-locked. The lock detector output signal may comprise a single bit value to indicate whether the PLL circuit is locked.

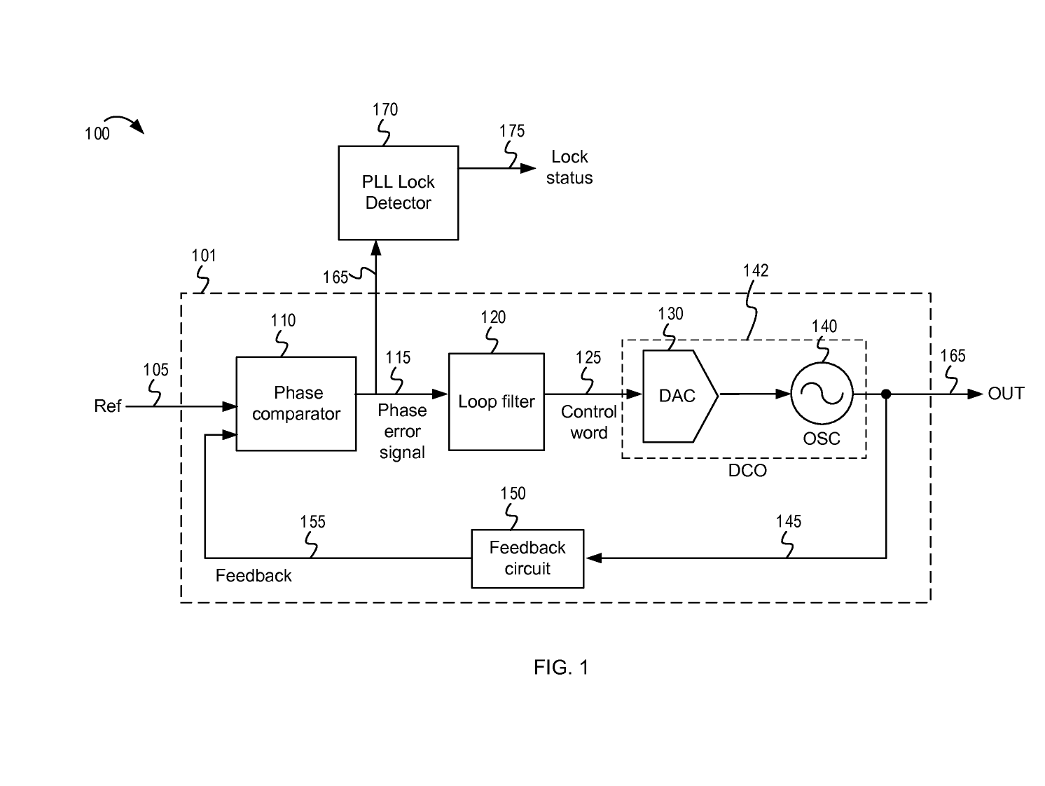

FIG. 1 is an example block diagram 100 of a digital phase locked loop (PLL) circuit 101 and PLL lock detector 170. The PLL circuit 101 is configured to receive a reference signal 105 and produce an output signal 165. Ideally the output signal 165 is locked in phase (e.g., synchronized) with the reference signal 105. In many embodiments, the output signal 165 may be considered locked in phase when the frequency of the output signal 165 matches the frequency of the reference signal 105 and the timing of output signal cycle transitions match the timing of the reference signal cycle transmissions. One way to visualize a phase lock is to consider “zero-cross” or some other indication of timing position with regard to the phase cycle of the reference signal and output signal. While there may be small variations in timing, ideally a phase locked loop would have a zero-cross event on the output signal 165 at about the same time as the zero-cross event on the reference signal 105.

The PLL circuit 101 includes a phase comparator 110 (sometimes also referred to as a phase detector). The phase comparator 110 receives the reference signal 105 and a feedback signal 155 and determines a phase error signal 115 based on a comparison of the reference signal 105 and the feedback signal 155. The phase error signal 115 carries information about how closely the feedback signal 155 aligns to the reference signal 105. The phase error signal 115 is sent to a loop filter 120 that generates a control word 125 based, at least in part, on the phase error signal 115. The control word 125 includes a configuration used by a digital-to-analog converter (DAC) 130 to control a controlled oscillator (OSC) 140. In some literature, the DAC 130 and OSC 140 may be referred together as a digitally controlled oscillator (DCO) 142. The DCO 142 generates the output signal 165 using oscillator circuitry.

In a phase locked loop circuit, a feedback mechanism is used to monitor or adjust the output of the oscillator circuitry to maintain a phase lock with the reference signal. In FIG. 1, the output 145 of the DCO 142 is passed through a feedback circuit 150 to generate the feedback signal 155 back to the phase comparator 110. The feedback circuit 150 may include a time-to-digital converter (TDC), counters, dividers, or other components to prepare the feedback signal 155 based, at least in part, on the output signal 145. In typical operation, as the output signal 145, 165 begins to shift out of phase (e.g., the time alignment of the phase is slightly misaligned) from the reference signal, small variations in the phase error signal 115 are passed through the components of the PLL circuit to cause corrections at the DCO 142.

A PLL lock detector 170 provides an indication to other components of an electronic device regarding whether the PLL circuit 101 is currently locked in phase with the reference signal 105. In traditional implementations, a PLL lock detector may monitor the output signal 145 or the feedback signal 155 to determine a comparison to the reference signal 105. However, additional phase comparator or signal shaping components were typically needed to compare the output or feedback signals to the reference signal. Complex circuitry to monitor zero cross boundaries and synchronization added complexity to the traditional PLL lock detector. In other traditional implementations, as stated previously, the control word 125 was used to determine lock status. However, in fine precision PLL circuits, the control word 125 may be a large signal (i.e., bit width) which typically required complex circuitry to manage calculations based, at least in part, on the control word 125.

In accordance with some embodiments of this disclosure, the PLL lock detector monitors the phase error signal 165 that is generated by the phase comparator 110. The phase error signal is already generated during normal operation of the PLL circuit 101, so the present disclosure does not require additional phase comparators to implement PLL lock detection. The PLL lock detector 170 manipulates the phase error signal 165 to determine whether the phase error signal indicates that the PLL circuit 101 is locked in phase with the reference signal 105. The PLL lock detector 170 generates a lock status signal 175 to indicate whether the PLL circuit 101 is phase locked. For example, the lock status signal 175 may be a binary signal that indicates a first value for locked or a second value for unlocked. Other components (not shown) of the electronic device may check the lock status signal 175 to determine whether the PLL circuit 101 is locked in phase with the reference signal 105.

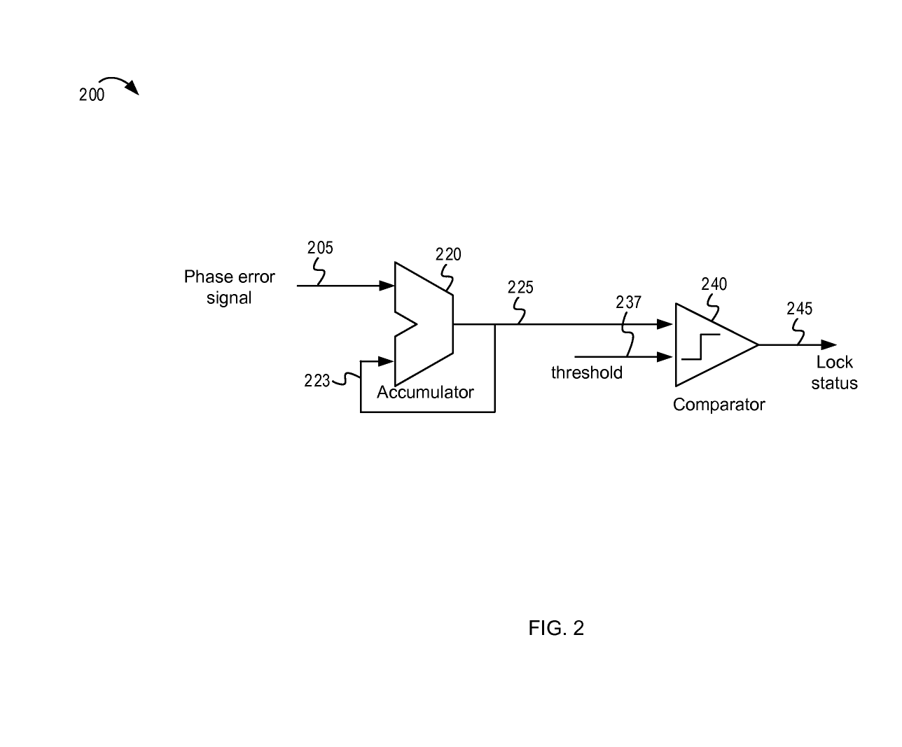

This disclosure provides several examples (such as those described in FIGS. 2-5) of how the PLL lock detector 170 utilizes the phase error signal 165 to determine whether the PLL circuit 101 is phase locked.

FIG. 2 is an example block diagram of a basic PLL lock detector 200 in accordance with at least one embodiment of the present disclosure. The PLL lock detector 200 includes an accumulator 220 (sometimes also referred to as an added) which adds a phase error signal 205 with a previous accumulated sum 223 of phase errors. The output of the accumulator 220 is a sum of phase errors 225. The sum of phase errors is also sometimes referred to as a phase error sum in this disclosure.

As described previously, the phase error signal 205 is received from a phase comparator that compares the feedback signal with the reference signal. Typically, the phase error signal 205 is a small value with positive or negative variations based, at least in part, on how well the feedback signal is in phase with the reference signal. Because the phase error signal 205 may include positive or negative values, the sum of the phase error signals 225 may be close to zero when the PLL circuit is locked in phase with the reference signal. As the phase error signal consistently includes more positive values, the control mechanisms of the PLL circuit should correct the oscillator, and eventually the phase error signal may include zero values or negative values. Therefore, in a locked (settled) PLL circuit the sum of the phase errors over a series of phase error signals should be near zero. The accumulator 220 may add a series of phase error signals to determine the sum of phase errors 225 over the series of phase error signals.

The magnitude of the phase error sum may be an indicator of how far out of phase the PLL circuit is in relation to the reference signal. Therefore, the PLL lock detector 200 includes a comparator 240 configured to compare the sum of phase errors 225 with a threshold value 237 to determine whether the PLL circuit is locked in phase. The threshold value 237 provides a hold down (e.g. hysteresis) type feature. For example, the threshold value 237 may be a numeric value (e.g. 10) that represents an acceptable amount of phase error for the PLL circuit to still be considered locked in phase. In the example, if the sum of the phase errors 225 is less than 10, then the comparator would generate a first lock status signal 245 indicating that the PLL circuit is locked in phase with the reference signal. In the example, if the sum of the phase errors 225 is greater than or equal to 10, then the comparator would generate a second lock status signal 245 indicating that the PLL circuit is not locked in phase with the reference signal. It should be understood that in some implementations the magnitude of the sum of phase errors 225 is utilized since large negative values and large positive values both indicate an out-of-phase condition. If only the magnitude of the sum of phase errors 225 is used, the example threshold value (10) provides a tolerance range for −10 to +10 of the phase error sum. In other examples, the threshold value may represent a range that includes both positive and negative values. If the sum of phase errors is within the range, the PLL circuit may be considered locked in phase, and if the sum of phase errors it outside the range, the PLL circuit may be considered out-of-phase.

By adjusting the threshold value 237, the PLL lock detector 200 may be configured for different phase error tolerance. For example, the threshold value 237 may be a configurable setting of the PLL lock detector 200. In one implementation, the threshold value 237 may be selected based on tolerance margin (such as 5% change in phase error sum) which is to be considered phase locked by the PLL lock detector 200.

The use of the phase error sum may allow the PLL lock detector 200 to utilize a smaller footprint in the physical circuit area because it needs fewer adder components. For example, the lock detector circuitry may be made up of three adder components—one adder in the accumulator 220 and two adders in the comparator 240. The fewer number of adder components and decreased complexity of the adders may allow the PLL lock detector of the present disclosure to be much less complex, be more power efficient and/or have a smaller physical area as compared to the traditional approach. For example, in one implementation, the PLL lock detector including features described in this disclosure may have a reduced area and lower power consumption of more than 70% over the traditional approach.

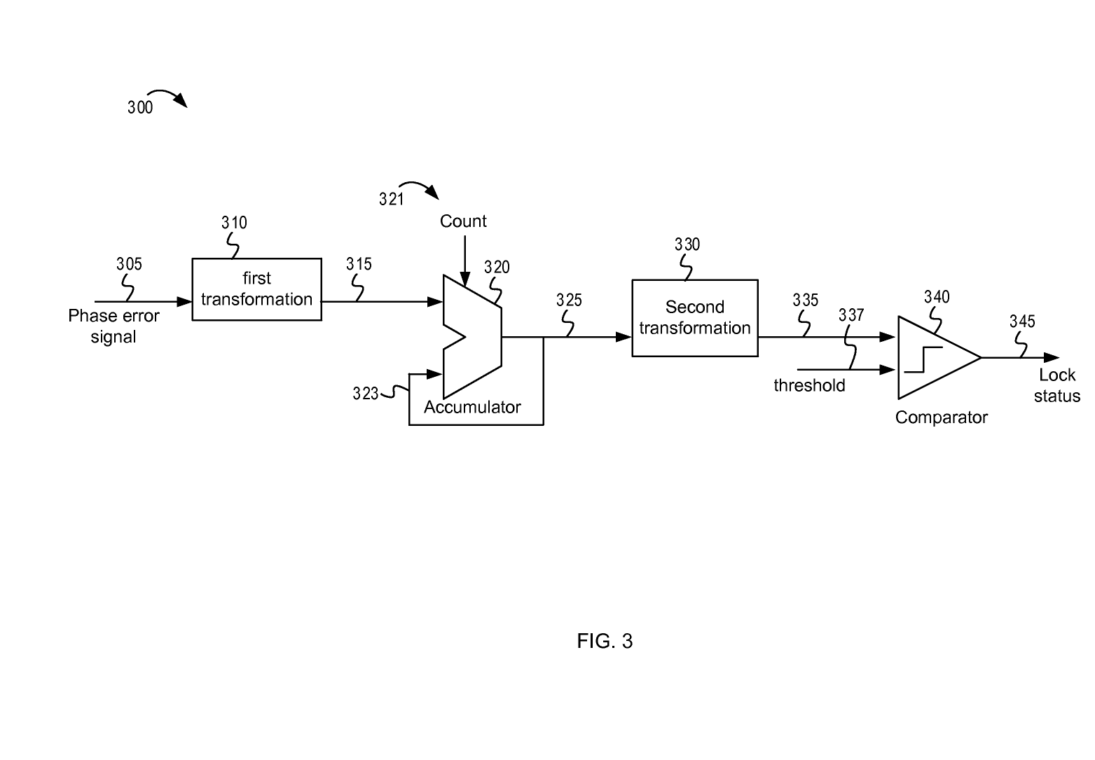

FIG. 3 is an example block diagram of an enhanced PLL lock detector 300 in accordance with at least one embodiment of the present disclosure. The enhanced PLL lock detector 300 is similar to the basic PLL lock detector 200 with some additional features. It should be understood that the features described may be used in various different orders or interchangeably with or without other features described in this and other Figures.

The phase error signal 305 is received from the phase comparator (not shown) of the PLL circuit. In FIG. 3, the phase error signal 305 may be transformed or altered using a first transformation 310. For example, the phase error signal 305 may be truncated, shifted, or low-pass filtered, to reduce the size of the phase error signal 305. The truncating, shifting, filtering, or truncating of the phase error signal may be referred together to as abridging in this disclosure. The abridged phase error signal 315 may be a smaller bit width than the original phase error signal 305. Because the abridged phase error signal 315 is a smaller bit width, the accumulator 320 may require less space or complexity to accumulate the abridged phase error signal 315 with the previous phase error sum 323 to generate a new phase error sum 325.

Referring to FIG. 3 to describe the configuration of the accumulator 320, a count value 321 may be a configurable setting to control how many phase error signals are included in the sum of phase errors. For example, the count indicates how many cycles or iterations of the accumulator should be executed prior to using the sum of phase errors to determine the lock status of the PLL circuit. In some embodiments, because the sum of phase errors is expected to be close to zero over a series of phase error signals, the count value 321 may be associated with averaging the phase error signals over a count-specified quantity of phase error signals. The sensitivity and delay of the PLL lock detector 300 may be adjusted by setting the count value 321 to a lower or higher number, respectively. A higher count value may result in a less sensitive PLL lock detector 300 but having a longer delay to determine the lock status. A lower count value may result in a more sensitive PLL lock detector 300 but having shorter delay to determine the lock status.

Continuing with FIG. 3, the sum of phase errors 325 from the accumulator 320 may be abridged using the second transformation 330. Similar to the first transformation 310, the second transformation 330 may include operations of truncating, filtering, shifting, or otherwise reducing the bit width associated with the sum of phase errors 325 to prepare an abridged phase error sum 335. The abridged phase error sum 335 is compared with a threshold value 337 by the comparator 340 to determine the lock status 345.

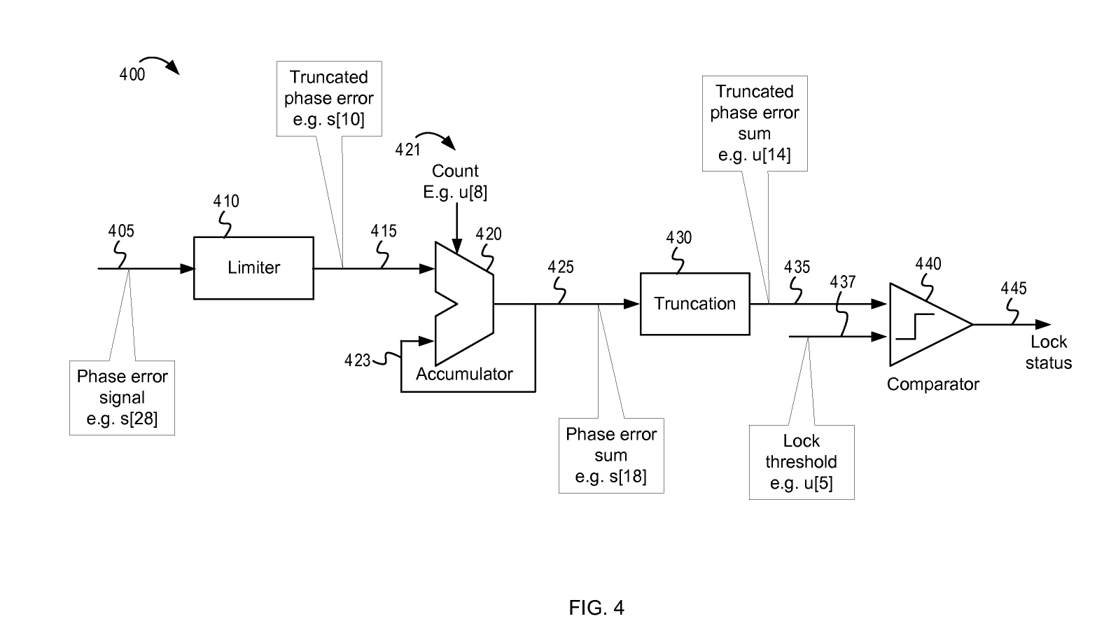

The first transformation 310 and second transformation 330 are added features in the enhanced PLL lock detector 300 but may reduce the power and space requirements of the PLL lock detector 300 because of the use of fewer bit-width adders in the accumulator 320 and comparator 340. FIG. 4 provides an example of one implementation using the first transformation 310 and second transformation 330 features.

FIG. 4 is an example block diagram of a particular implementation of a PLL lock detector 400 in accordance with an embodiment of the present disclosure. In FIG. 4, the lengths and types of various signals are described using abbreviated references, in which “s” is defined as a signed value, “u” is defined as an unsigned value, and the numeric value following the type represents the quantity of bits in the value. For example, “s[28]” represents a signed 28-bit word, while “u[8]” represents an unsigned 8 bit word.

In FIG. 4, a phase error signal 405 is received from the phase comparator (not shown) of the PLL circuitry. The phase error signal 405 may be represented as a signed 28 bit word. In FIG. 4, the phase error signal 405 is passed through a limiter 410 that reduces the bit-width of the phase error signal down 405 to a 10 bit word. In one example embodiment, the limiter removes the 8 least-significant bits and then truncates the 10 most-significant bits. The loss of resolution from the least significant bits and most significant bits of the phase error signal 405 may not impact the utility of the PLL lock detector 400, since the PLL lock detector 400 utilizes a sum (i.e., average) of a set of phase error signals 405. In the example of FIG. 4, the accumulator 420 may add up to 255 of the truncated phase error values 415. The 8-bit count value 421 may be used to represent a number from 1 to 255 to indicate to the accumulator 420 how many truncated phase error values 415 should be accumulated. The count value 421 may be set based, at least in part, on sensitivity and/or delay requirements of the PLL lock detector 400. In one embodiment, the accumulator 420 may be limited to 255 accumulated values to low-pass filter the phase error sum. Each time the accumulator 420 reaches the number of accumulated values specified by the count value 421, the accumulator 420 may send the phase error sum 425 and reset the accumulator 420 back to zero.

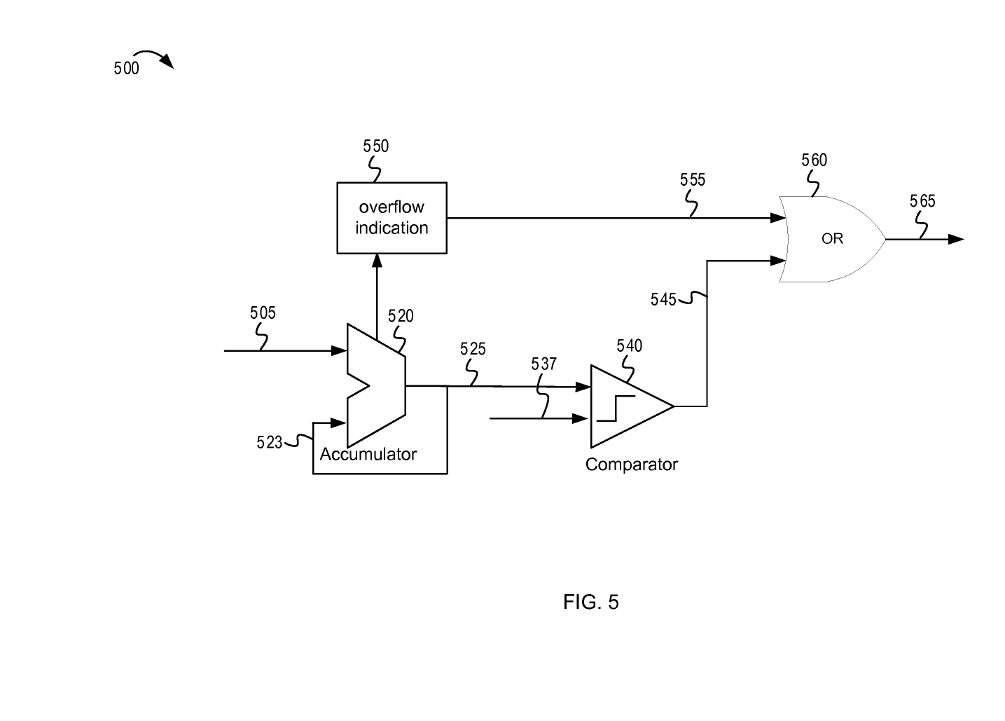

In one implementation, the accumulator 420 can be implemented using a single 18-bit adder. Because the size of the accumulator 420 is capable of accumulating an 18-bit word value and the truncated phase error signal 415 is represented as a 10-bit word value, the accumulator 420 may not experience an overflow condition (with are further describe in relation to FIG. 5). The output of the accumulator 420 is a phase error sum 425 represented a signed 18-bit word. The phase error sum 425 may be further truncated at a truncation unit 430. The truncation unit 430 may remove the 4 least-significant-bits of the phase error sum 425. It should be understood that truncating may also be performed using shifting or other operations to condition the phase error sum 425 to the truncated phase error um 435. The truncated phase error sum 435 may also be an unsigned value since the magnitude of the truncated phase error sum is used by the comparator 440. The truncated phase error sum 435 is compared with a lock threshold value 437 at comparator 440. The lock threshold value in FIG. 4 is represented as a 5-bit unsigned number. Based on the result of the comparator 440, the lock status signal 445 may indicate whether the PLL is considered locked. The lock status signal 445 may be represented as a single bit value.

It should be understood that other configurations of limiters, accumulators, truncating components, or comparators may be used. Furthermore, various selections of bit lengths or bits to truncate or compare may also be used in accordance with this disclosure.

FIG. 5 is an example block diagram of a PLL lock detector 500 having overflow condition logic in accordance with at least one embodiment of the present disclosure. Similar to FIG. 2, the PLL lock detector 500 includes an accumulator 520 configured to accumulate a sum of phase errors 525, e.g., by adding a phase error signal 505 with a previous sum of phase errors 523. The accumulator 520 may add a series of phase error signals based on a configurable count setting (not shown). The sum of phase errors 525 is compared with a threshold value 537 by a comparator 540 to generate a lock comparison signal 545.

In FIG. 5, an overflow feature is added as another way to determine a lock status of the PLL circuit. The accumulator 520 may be implemented with an overflow capability. An output of the accumulator 520 may include an overflow indication that indicates that an overflow has occurred. An overflow condition occurs when the sum of phase errors is larger than can be represented by the size of the accumulator 520. The overflow indication may be implemented as an overflow bit (not shown) in the sum of the phase errors 525.

At 550, the overflow indication may be used to determine that the PLL circuit is not phase locked. For example, if the sum of phase errors is so large that the accumulator 520 overflows, the overflow indicator may be used to determine that the PLL circuit is out of phase with the reference signal regardless of whether the sum of phase errors has been compared to the threshold value yet. Therefore, for example, when the accumulator 520 is configured to count a larger number of phase error signals, the overflow indication can also be used to reset the accumulator 520.

In a typical implementation, a positive value (e.g., binary “1”) may indicate an overflow condition. The overflow indication signal 555 may be used with an “OR” logic component 560. If either the lock comparison signal 545 or the overflow indication signal 555 indicate that the PLL circuit is not locked, then the OR logic component 560 will output a lock status signal 565 to indicate that the PLL circuit is not locked with the reference signal. Other variations in which a phase error signal is used in a lock detector circuit may be readily conceived based on the foregoing disclosure and example figures.

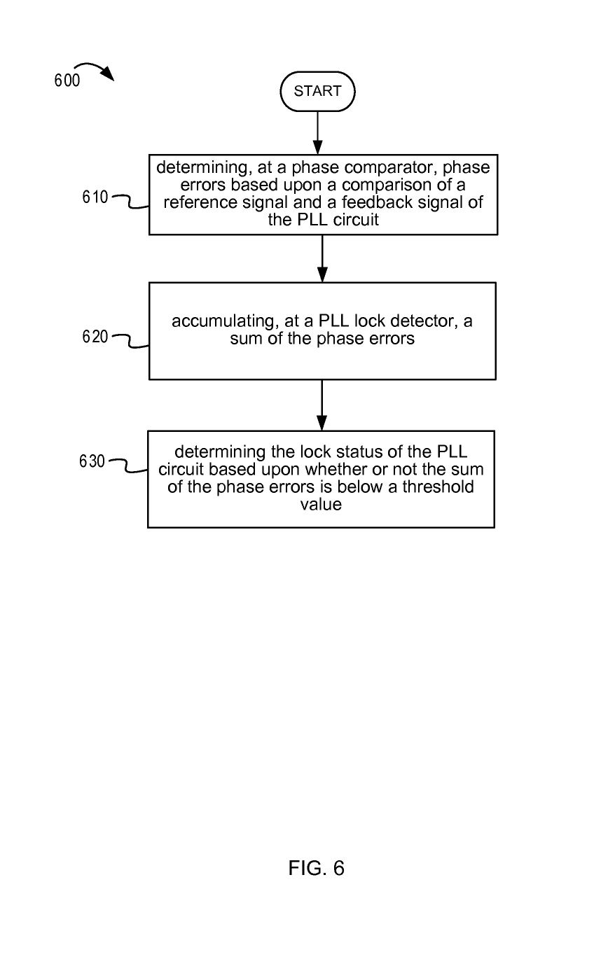

FIG. 6 is a flow diagram showing example operations 600 for use with a PLL lock detector in accordance with an embodiment of the present disclosure. At 610, an operation may include determining, at a phase comparator, phase errors based, at least in part, on a comparison of a reference signal and a feedback signal of the PLL circuit. At 620, an operation may include accumulating, at a PLL lock detector, a sum of the phase errors. At 630, an operation may include determining the lock status of the PLL circuit based, at least in part, on whether the sum of the phase errors is below a threshold value.

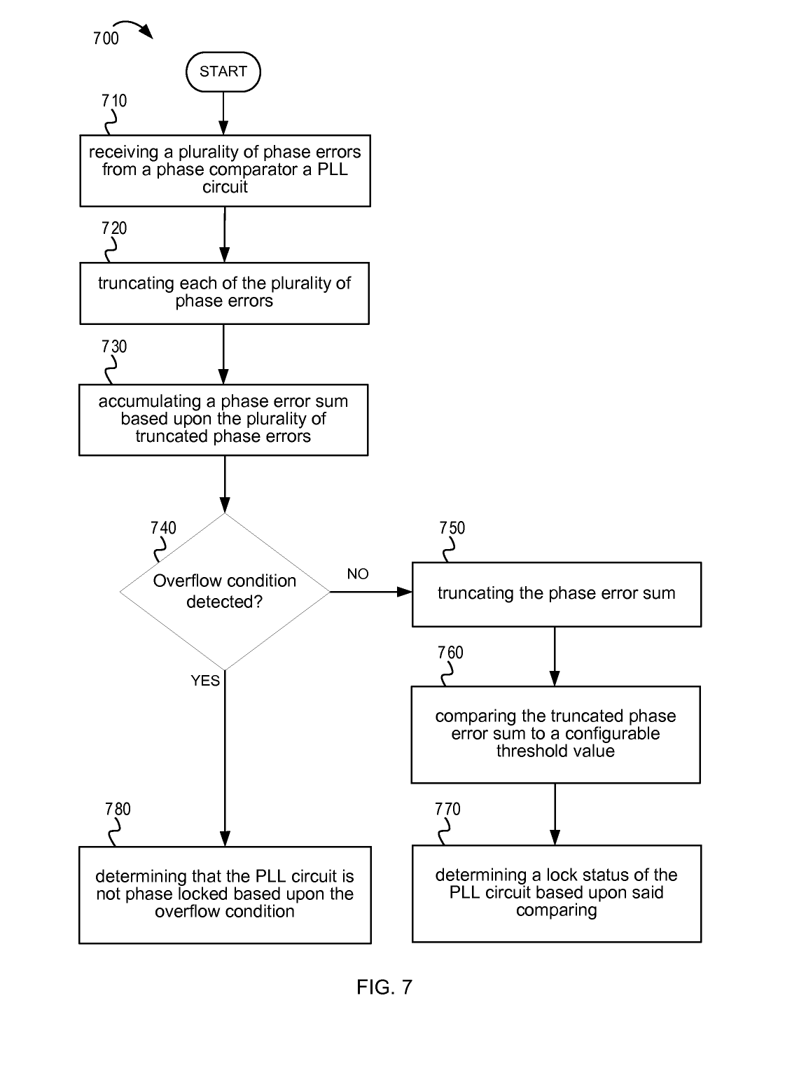

FIG. 7 is a flow diagram showing example operations 700 for use with a PLL lock detector in accordance with an embodiment of the present disclosure.

At 710, an operation may include receiving a plurality of phase error signals from a phase comparator a PLL circuit. The phase comparator may be an existing component already used in the PLL circuit for controlling the PLL circuit.

At 720, an operation may include truncating each of the plurality of phase error signals. At 730, an operation may include accumulating a phase error sum based, at least in part, on the plurality of truncated phase error signals. The accumulating may be performed by an accumulator component or components.

At 740, if the accumulator may be configured with an overflow capability, an operation may include detecting whether an overflow condition has occurred. For example, the overflow condition may be indicative that the phase error sum is beyond a capacity of the accumulator. If an overflow condition is detected, the flow continues to block 780. If an overflow condition is not detected, or if the overflow capability is not implemented, the flow continues to block 750.

At 750, an operation may include truncating the phase error sum. At 760, an operation may include comparing the truncated phase error sum to a configurable threshold value. The comparing may be performed by a comparator component or components. At 770, an operation may include determining a lock status of the PLL circuit based, at least in part, on said comparing.

At 780, an operation may include determining that the PLL circuit is not phase locked based, at least in part, on the overflow condition.

It should be understood that FIGS. 1-7 and the operations described herein are examples meant to aid in understanding embodiments and should not be used to limit embodiments or limit scope of the claims. Embodiments may perform additional operations, fewer operations, operations in a different order, operations in parallel, and some operations differently.

As will be appreciated by one skilled in the art, aspects of the present inventive subject matter may be embodied as a system, method, or computer program product. Accordingly, aspects of the present inventive subject matter may take the form of an entirely hardware embodiment, a software embodiment (including firmware, resident software, micro-code, etc.) or an embodiment combining software and hardware aspects that may all generally be referred to herein as a “circuit,” “module” or “system.” Furthermore, aspects of the present inventive subject matter may take the form of a computer program product embodied in one or more computer readable medium(s) having computer readable program code embodied thereon.

Any combination of one or more non-transitory computer readable medium(s) may be utilized. Non-transitory computer-readable media comprise all computer-readable media, with the sole exception being a transitory, propagating signal. The non-transitory computer readable medium may be a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Computer program code embodied on a computer readable medium for carrying out operations for aspects of the present inventive subject matter may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present inventive subject matter are described with reference to flowchart illustrations and/or block diagrams of methods, apparatus (systems) and computer program products according to embodiments of the inventive subject matter. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

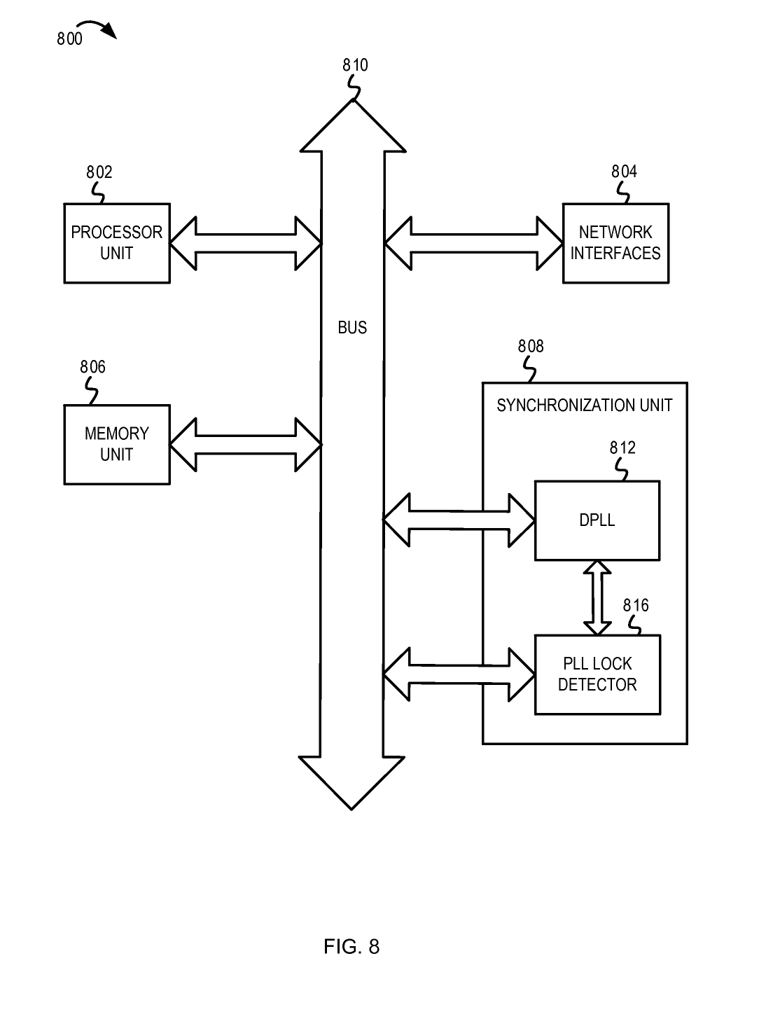

FIG. 8 is an example block diagram of one embodiment of an electronic device 800 including a digital phase lock loop 812 and a PLL lock detector 816 in accordance with this disclosure. In some implementations, the electronic device 800 may be one of a laptop computer, a netbook, a mobile phone, a powerline communication device, a personal digital assistant (PDA), or other electronic systems comprising a hybrid communication unit configured to exchange communications across multiple communication networks (which form the hybrid communication network). The electronic device 800 may include a processor unit 802 (possibly including multiple processors, multiple cores, multiple nodes, and/or implementing multi-threading, etc.). The electronic device 800 may include a memory unit 806. The memory unit 806 may be system memory (e.g., one or more of cache, SRAM, DRAM, zero capacitor RAM, Twin Transistor RAM, eDRAM, EDO RAM, DDR RAM, EEPROM, NRAM, RRAM, SONOS, PRAM, etc.) or any one or more of the above already described possible realizations of machine-readable media. The electronic device 800 may also include a bus 810 (e.g., PCI, ISA, PCI-Express, HyperTransport®, InfiniBand®, NuBus, AHB, AXI, etc.), and network interfaces 804 that include at least one of a wireless network interface (e.g., a WLAN interface, a BLUETOOTH® (Bluetooth) interface, a WiMAX interface, a ZigBee® interface, a Wireless USB interface, etc.) and a wired network interface (e.g., an Ethernet interface, a powerline communication interface, etc.). In some implementations, the electronic device 800 may support multiple network interfaces—each of which is configured to couple the electronic device 800 to a different communication network.

The electronic device 800 also includes the digital phase lock loop 812 and the PLL lock detector 816. As described above in FIGS. 1-7, the PLL lock detector 816 may implement functionality to determine whether the DPLL 812 is locked in phase with a reference signal. In some embodiments, the DPLL 812 and PLL lock detector 816 may be included as part of a synchronization unit 808 or other collection of circuits for use in the electronic device 800. It should be understood, that in some embodiments, the synchronization unit 808 or collection of circuits may also be implemented either as part of or in coordination with a dedicated processor (e.g., such as a timing unit comprising part of a system on a chip, or board with multiple chips, or multiple boards, in which the communication may have one or more dedicated processor or processing unit(s), in addition to the main processor 802). Any one of these functionalities may be partially (or entirely) implemented in hardware and/or on the processor unit 802. For example, the functionality may be implemented with an application specific integrated circuit, in logic implemented in the processor unit 802, in a co-processor on a peripheral device or card, etc. Further, realizations may include fewer or additional components not illustrated in FIG. 8 (e.g., video cards, audio cards, additional network interfaces, peripheral devices, etc.). The processor unit 802, the memory unit 806, and the network interfaces 806 are coupled to the bus 810. Although illustrated as being coupled to the bus 810, the memory unit 806 may be coupled to the processor unit 802.

While the embodiments are described with reference to various implementations and exploitations, it will be understood that these embodiments are illustrative and that the scope of the inventive subject matter is not limited to them. In general, enhanced tone maps as described herein may be implemented with facilities consistent with any hardware system or hardware systems. Many variations, modifications, additions, and improvements are possible.

What is claimed is:

1. A phase-locked loop (PLL) circuit comprising:
a phase comparator configured to:
determine a first phase error between a reference signal and a feedback signal of the PLL circuit, and
determine a second phase error between the reference signal and the feedback signal of the PLL circuit; and
a PLL lock detector configured to:
determine a sum of the first phase error and the second error, and
determine whether the sum is below a threshold value.

2. The PLL circuit of claim 1, wherein:
the phase comparator is further configured to periodically determine further phase errors between the reference signal and the feedback signal of the PLL circuit; and
the PLL lock detector is further configured to:
determine a sum of the first phase error, second phase error, and further phase errors; and
determine the PLL circuit is locked in phase with the reference signal if the sum is below a threshold value.

3. The PLL circuit of claim 1, wherein the PLL lock detector comprises:
an accumulator configured to determine the sum; and
a comparator configured to compare the sum with the threshold value to determine if the PLL circuit is locked in phase with the reference signal.

4. The PLL circuit of claim 3, wherein the phase lock detector further comprises:
a digital limiter configured to receive the first and second phase errors from the phase comparator and abridge the first and second phase errors prior to the accumulator determining the sum.

5. The PLL circuit of claim 3, wherein the PLL lock detector further comprises:
a truncation component configured to reduce a bit length of the sum from the accumulator prior to sending a truncated phase error sum to the comparator, wherein the comparator is configured to compare the truncated phase error sum with the threshold value to determine if the PLL circuit is locked in phase with the reference signal.

6. The PLL circuit of claim 3, wherein an overflow condition is caused when the sum is beyond a capacity of the accumulator, and wherein the PLL lock detector further comprises:
a logic component that combines an indicator of the overflow condition and an output of the comparator to generate a PLL lock detector output signal configured to indicate if the PLL circuit is locked in phase with the reference signal.

7. The PLL circuit of claim 1, wherein the threshold value is configurable.

8. The PLL circuit of claim 1, wherein the PLL circuit comprises an all-digital phase-locked loop circuit.

9. A method for use with a phase-locked loop (PLL) circuit, the method comprising:
determining, at a phase comparator, a first phase error between a reference signal and a feedback signal of the PLL circuit;
determining, at the phase comparator, a second phase error between the reference signal and the feedback signal of the PLL circuit;
determining, at a PLL lock detector, a sum of the first phase error and the second phase error; and
determining whether the sum is below a threshold value.

10. The method of claim 9, further comprising:
periodically determining further phase errors between the reference signal and the feedback signal of the PLL circuit;
determining a sum of the first phase error, second phase error, and further phase errors; and
determining the PLL circuit is locked in phase with the reference signal if the sum is below a threshold value.

11. The method of claim 9, wherein the threshold value is a configurable setting of the PLL lock detector.

12. The method of claim 9, further comprising:
truncating each phase error from the phase comparator prior to adding each phase error to the sum.

13. The method of claim 9, further comprising:
comparing the sum to the threshold value.

14. The method of claim 13, further comprising:
truncating the sum prior to said comparing the sum to the threshold value.

15. The method of claim 9, wherein said determining the sum comprises:
adding a quantity of phase errors from the phase comparator, wherein the quantity of phase errors to add is a configurable setting of the PLL lock detector.

16. The method of claim 9, further comprising:
outputting a lock status signal having one of two states, the two states associated with indicating that the PLL circuit is phase locked or unlocked, the lock status based, at least in part, on whether the sum is below the threshold value.

17. The method of claim 9, further comprising:
detecting an overflow condition indicative that the sum is beyond a capacity of an accumulator; and
determining that the PLL circuit is not phase locked based, at least in part, on the overflow condition.

18. An electronic device comprising:
a digital phase locked loop (PLL) circuit that determines a phase error signal in association with a control portion of the PLL circuit; and
a PLL lock detector configured to observe the phase error signal and output a lock status signal based, at least in part, on an accumulation of a plurality of phase error signal values.

19. The electronic device of claim 18, wherein the PLL lock detector is configured to output the lock status signal based, at least in part, on the plurality of phase error signal values indicating phase errors between a reference signal and a feedback signal.

20. The electronic device of claim 18, wherein the accumulation of the plurality of phase error signal values is compared with a configurable threshold value to determine the lock status signal.

21. An apparatus comprising:
a digital phase locked loop (PLL) circuit; and
means for detecting a lock status of the PLL circuit based, at least in part, on an accumulation of phase error values from a phase comparator of the PLL circuit.

22. The apparatus of claim 21, further comprising:
a means for periodically determining phase errors between a reference signal and a feedback signal of the PLL circuit; and
wherein the means for detecting the lock status includes
means for determining a sum of the phase errors, and
means for determining whether the PLL circuit is locked in phase with the reference signal based, at least in part, on whether the sum of the phase errors is below a threshold value.

23. The apparatus of claim 22, wherein the means for detecting the lock status includes:
a means for receiving the phase errors from the phase comparator and means to abridge the phase errors prior to determining the sum of the phase errors.

24. The apparatus of claim 22, wherein the means for detecting the lock status includes:
a means for reducing a bit length of the sum of the phase errors to determining whether the PLL circuit is locked in phase, wherein the means for determining whether the PLL circuit is locked in phase is configured to compare the truncated phase error sum with the threshold value to determine whether the PLL circuit is locked in phase with the reference signal.

25. The apparatus of claim 22, wherein the threshold value is configurable.
